(19) United States
(12) Patent Application Publication
(10) Pub. No.: US 2010/0007609 A1
(43) Pub. Date: Jan. 14, 2010

(54) KEYBOARD, ELECTRONIC DEVICE, AND KEYBOARD MANUFACTURING METHOD

(75) Inventors: Manabu Watabe, Nagano (JP); Kenji Saito, Nagano (JP); Ryosuke Tobiyama, Tokyo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Sony Corporation, Tokyo (JP)

(21) Appl. No.: 12/486,198

(22) Filed: Jun. 17, 2009

(30) Foreign Application Priority Data
Jul. 11, 2008 (JP) 2008-108911
Jul. 11, 2008 (JP) P2008-180911

(51) Int. Cl. G06F 3/02; H03M 11/00

(52) U.S. Cl. 345/168; 341/22

(57) ABSTRACT

A keyboard includes a keyboard unit, a frame, and an exterior panel. The keyboard unit includes a surface made of metal, and a plurality of keys disposed on the surface. The frame made of resin is joined to the surface, the frame including a plurality of first openings into which the respective keys are inserted. The exterior panel made of metal is detachably bonded to the frame, the exterior panel including a plurality of second openings into which the respective keys protruding from the respective first openings of the frame are inserted.

### BACKGROUND OF THE INVENTION

1. Field of the Invention

The present invention relates to a keyboard used for a laptop personal computer or the like, an electronic device such as a laptop personal computer including the keyboard, and a keyboard manufacturing method.

2. Description of the Related Art

It is necessary to provide different keyboards to laptop personal computers depending on destination positions. Further, a keyboard unit and a palm rest for fixing the keyboard unit from above are often attached/detached for maintenance.

Japanese Patent Application Laid-open No. HEI 07-64670 (paragraph [0003], FIG. 4) (hereinafter, referred to as Patent Document 1) discloses the technique in which an upper casing and a lower casing are fixed to each other by screws while interposing a keyboard unit to thereby constitute a main body side of a laptop personal computer. (For example, see Patent Document 1).

### SUMMARY OF THE INVENTION

In the technique disclosed in Patent Document 1, because a center area of the keyboard unit is not fixed in position by the upper casing, rigidity of a keyboard is low and a keystroke feeling is poor. For example, by welding a center area of a keyboard unit to an upper casing using a welding pin protruding from the upper casing made of resin, those problems are eliminated. However, the welding pin needs to be cut off in maintenance, and thus the upper casing cannot be reused. Furthermore, by welding an upper casing made of metal to the center area of the keyboard unit, problems such as the rigidity of the keyboard are eliminated. However, both of them are directly welded to each other, and accordingly the upper casing is difficult to be reused.

In view of the above circumstances, there is a need for a keyboard that has high rigidity and whose casing can be reused, an electronic device, and a keyboard manufacturing method.

According to an embodiment of the present invention, there is provided a keyboard including a keyboard unit, a frame, and an exterior panel. The keyboard unit includes a surface made of metal, and a plurality of keys disposed on the surface. The frame is made of resin, is joined to the surface, and includes a plurality of first openings into which the respective keys are inserted. The exterior panel is made of metal, is detachably bonded to the frame, and includes a plurality of second openings into which the respective keys protruding from the respective first openings of the frame are inserted.

In the embodiment of the present invention, the frame is joined to the surface of the keyboard unit, and the exterior panel is detachably bonded to the frame. Accordingly, the keyboard is provided with a structure in which a gap is not generated between the surface of the keyboard unit and the exterior panel, with result that rigidity of the keyboard can be enhanced. Furthermore, the exterior panel is made of metal and is detachably bonded to the frame. Accordingly, the exterior panel can be detached from the frame as necessary and can be reused.

The exterior panel and the frame may be bonded to each other with a tape to which an adhesive is applied on both sides.

Accordingly, because the exterior panel is detachably bonded to the frame with the tape, the exterior panel can be detached from the frame more easily.

The tape may be a tape having perforations for facilitating separation.

Accordingly, because the tape has the perforations, the exterior panel can be peeled off more easily when detached from the frame.

The frame may be divided into areas corresponding to a plurality of areas that partition an area of the keyboard unit on which the plurality of keys are arranged.

Accordingly, in a case where the exterior panel made of metal and the frame made of resin are detachably bonded to each other with the tape, even when temperatures of the exterior panel and the frame change from high to low, it is possible to absorb a difference in contraction ratio due to a temperature difference between the respective materials, and to attach the exterior panel and the frame more reliably. Furthermore, in a case where the arrangement of the keys is varied depending on destination positions, such a variation can be supported with the divided frames each having different shapes. Accordingly, reduction in costs for the frame can be achieved.

The exterior panel may include a hole used for positioning with respect to the keyboard unit, into which a shock-absorbing member may be inserted.

Accordingly, the hole used for positioning of the keyboard unit and the external panel can also be used as a hole to which a shock-absorbing member is inserted.

The keyboard may be connected to a display portion including a display screen so that the display portion is foldable with respect to the keyboard, and the shock-absorbing member may absorb a shock caused between the keyboard and the display portion when the display portion is folded with respect to the keyboard.

Accordingly, when the display portion is folded with respect to the keyboard, a shock caused between the display portion and the keyboard can be absorbed by the shock-absorbing member.

According to another embodiment of the present invention, there is provided an electronic device including a keyboard and a display portion. The keyboard includes a keyboard unit, a frame, and an exterior panel. The keyboard unit includes a surface made of metal and a plurality of keys disposed on the surface. The frame is made of resin, is joined to the surface, and includes a plurality of first openings into which the respective keys are inserted. The exterior panel is made of metal, is detachably bonded to the frame, and includes a plurality of second openings into which the respective keys protruding from the respective first openings of the frame are inserted. The display portion displays an image based on a display signal that is generated in the keyboard by pressing of the keys of the keyboard.

In the embodiment of the present invention, the frame is joined to the surface of the keyboard unit, and the exterior panel is detachably bonded to the frame. Accordingly, the keyboard is provided with a structure in which a gap is not generated between the surface of the keyboard unit and the exterior panel, with result that rigidity of the keyboard can be enhanced. Furthermore, the exterior panel is made of metal and is detachably bonded to the frame. Accordingly, the exterior panel can be detached from the frame as necessary and can be reused.

According to another embodiment of the present invention, there is provided a keyboard manufacturing method, including joining a frame made of resin to a surface made of metal of a keyboard unit, the frame including a plurality of first openings, the keyboard unit including the surface and a plurality of keys disposed on the surface, in a state where the respective keys are inserted into the first openings. An exterior panel and the frame are aligned with each other, the exterior panel including a plurality of second openings into which the respective keys are inserted. The exterior panel is detachably bonded to the frame in a state where the respective keys are inserted into the second openings.

In the embodiment of the present invention, the frame is joined to the surface of the keyboard unit, and the exterior panel is detachably bonded to the frame. Accordingly, the keyboard is provided with a structure in which a gap is not generated between the surface of the keyboard unit and the exterior panel, with result that rigidity of the keyboard can be enhanced. Furthermore, the exterior panel is made of metal and is detachably bonded to the frame. Accordingly, the exterior panel can be detached from the frame as necessary and can be reused. Moreover, the keyboard unit to which the frame is joined and the exterior panel have only to be aligned in a state where the frame is joined to the keyboard unit. Accordingly, the alignment of the exterior panel and the keyboard unit, which is originally necessary, can be achieved without aligning the frame with the exterior panel.

In the keyboard unit, a first positioning hole used for alignment with the exterior panel is formed. In the exterior panel, a second positioning hole used for alignment with the keyboard unit is formed. The keyboard unit and the exterior panel are aligned with each other by inserting a jig into the first positioning hole and the second positioning hole. The bonding may be performed using a tape to which an adhesive is applied on both sides.

Accordingly, the jig is inserted into the first positioning hole of the keyboard unit and the second positioning hole of a casing to align the keyboard unit and the exterior panel more easily, and the exterior panel and the keyboard unit can be bonded to each other with the tape.

The keyboard may constitute a main body portion of a folding-type laptop personal computer, and the second positioning hole of the exterior panel that is bonded to the frame may be inserted with a shock-absorbing member, the shock-absorbing member absorbing a shock caused when a display portion that is provided so as to be openable with respect to the main body portion is closed with respect to the main body portion.

Accordingly, the second positioning hole can be used to align the keyboard unit and the exterior panel, and can be used as a hole for inserting the shock-absorbing member. In other words, the exterior panel is made of metal and is an appearance part, and accordingly a hole for positioning may be impossible to be formed on the exterior panel. However, the alignment is performed using the second positioning hole and then the shock-absorbing member is inserted into the second positioning hole, whereby the alignment can be made without impairing the appearance of the exterior panel.

As described above, according to the embodiments of the present invention, a keyboard that has high rigidity and whose casing can be reused can be provided.

These and other objects, features and advantages of the present invention will become more apparent in light of the following detailed description of best mode embodiments thereof, as illustrated in the accompanying drawings.

### BRIEF DESCRIPTION OF DRAWINGS

FIG. 1 is a perspective view of an electronic device according to an embodiment of the present invention in an opened state;

FIG. 2 is a perspective view of the electronic device shown in FIG. 1 in a closed state;

FIG. 3 is an exploded perspective view of a main body portion of the electronic device;

FIG. 4 is an exploded perspective view of a keyboard assembly shown in FIG. 3;

FIG. 5 is a bottom view of the keyboard assembly shown in FIG. 3;

FIG. 6 is a cross-sectional view taken along the line A-A of the keyboard assembly shown in FIG. 5;

FIG. 7 is a plan view of an electronic component built-in unit of the electronic device;

FIG. 8 is a flowchart showing a bonding step of a keyboard unit to a first casing;

FIG. 9 is a plan view showing the vicinity of a positioning portion at a time of alignment;

FIG. 10 is a cross-sectional view taken along the line B-B of the positioning portion shown in FIG. 9;

FIG. 11 is a plan view showing the vicinity of a positioning portion at a time of alignment; and

FIG. 12 is a cross-sectional view taken along the line C-C of the positioning portion shown in FIG. 11.

### DESCRIPTION OF PREFERRED EMBODIMENTS

Hereinafter, an embodiment of the present invention will be described with reference to the drawings.

In this embodiment, a description will be given on an electronic device while taking a laptop personal computer as an example.

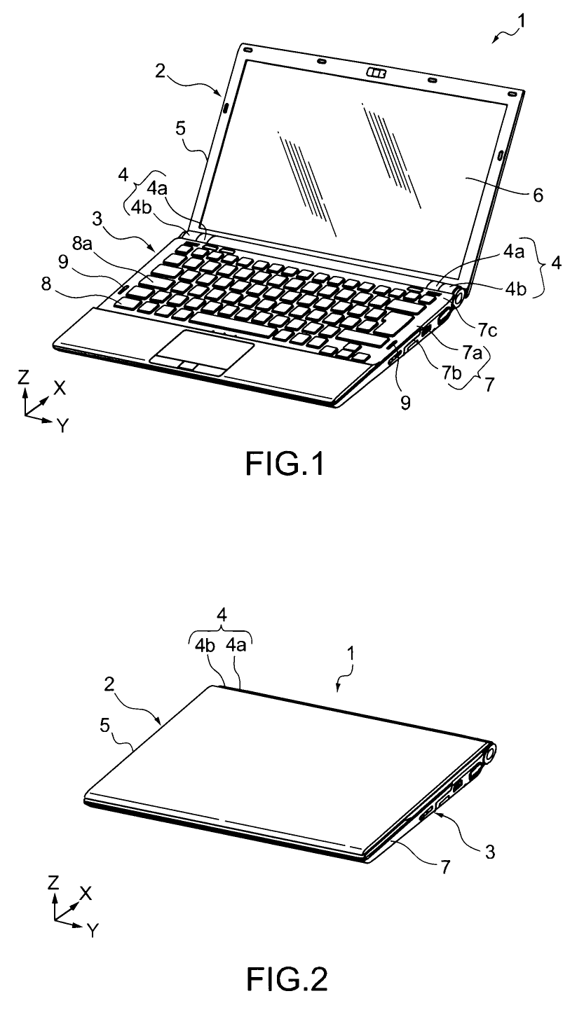

FIG. 1 is a perspective view of an electronic device according to an embodiment of the present invention in an opened state, and FIG. 2 is a perspective view of the electronic device shown in FIG. 1 in a closed state.

An electronic device 1 includes a display portion 2, a main body portion 3, and a hinge 4 for coupling the display portion 2 and the main body portion 3.

The display portion 2 is openable (foldable) with respect to the main body portion 3 through the hinge 4. The display portion 2 includes a display-side casing 5, a display surface 6, and a display processing unit (not shown) that is provided in the display-side casing 5 and performs a display processing.

The display-side casing 5 is a casing of the display portion 2, that contains the display processing unit (not shown). The display surface 6 displays information, and faces the main body portion 3 in the closed state. To display-side casing 5, two cylindrical-shaped connection portions 4a are provided. Those two connection portions 4a are connected with connection portions 4b of the main body (described later) to constitute the hinge 104.

The main body portion 3 includes a casing 7 and a build-in unit such as a keyboard unit 8 that is accommodated in the casing 7. As shown in FIG. 1, the casing 7 includes a first casing 7a (palm rest) as an exterior panel and a second casing 7b.

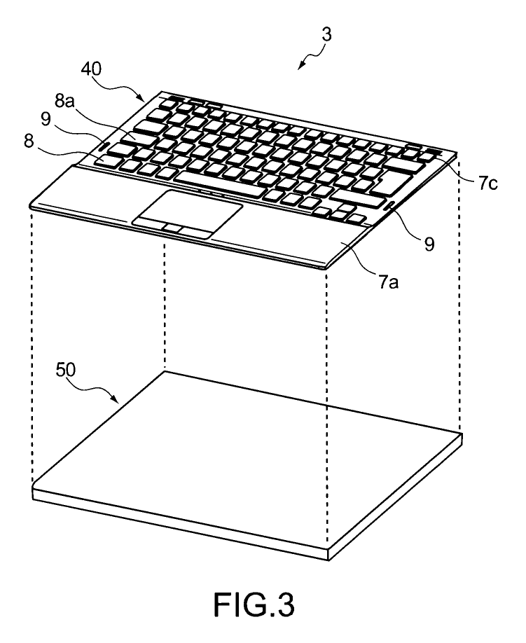

FIG. 3 is an exploded perspective view of the main body portion 3.

The main body portion 3 includes a keyboard assembly 40 provided with the keyboard unit 8, and an electronic component built-in unit 50 from which the keyboard assembly 40 is detachable, the electronic component built-in unit 50 being described below. The keyboard assembly 40 and the electronic component built-in unit 50 are fixed to each other with screws or the like (not shown).

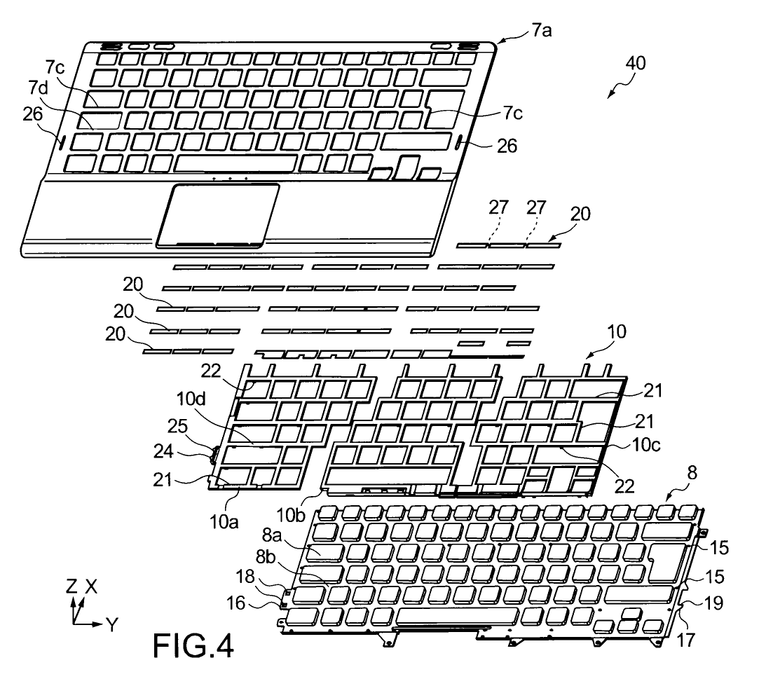

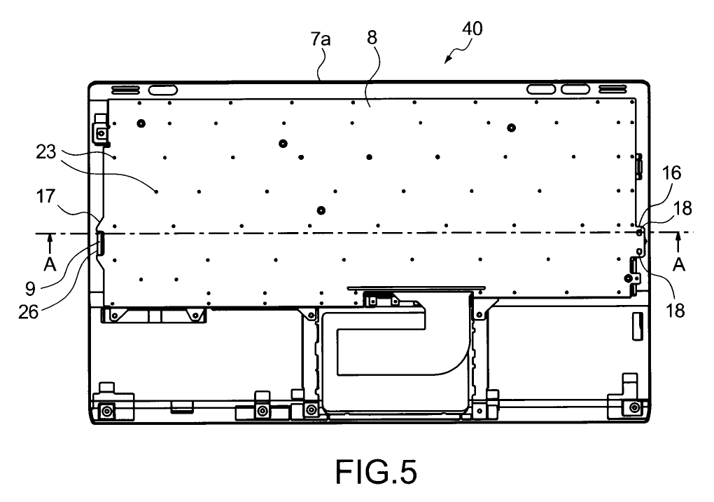

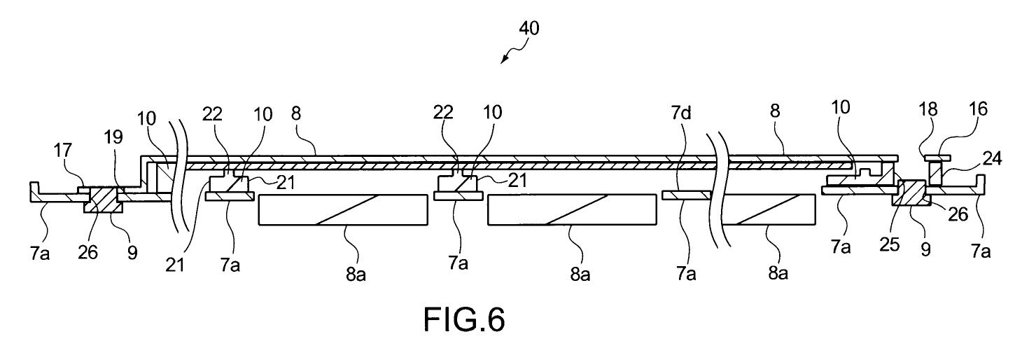

FIG. 4 is an exploded perspective view of the keyboard assembly 40 shown in FIG. 3. FIG. 5 is a bottom view of the keyboard assembly 40 shown in FIG. 3. FIG. 6 is a cross-sectional view taken along the line A-A of the keyboard assembly 40 shown in FIG. 5.

The keyboard assembly 40 includes, as shown in FIG. 4, the keyboard unit 8, a frame 10, and the first casing 7a. As described below, the first casing 7a and the frame 10 are integrally structured as shown in FIG. 3 by detachable bonding or the like.

As shown in FIG. 4, the keyboard unit 8 includes a plurality of keys 8a, for example, and functions as an input portion of the electronic device 1. An upper surface 8b or the like of the keyboard unit 8, on which the keys 8a are disposed so as to be pressed downward, is made of, for example, metal. A plurality of welding holes 15 are formed at predetermined intervals on the upper surface 8b of the keyboard unit 8. The welding holes 15 are used for welding of the keyboard unit 8 and the frame 10 as described below.

The keyboard unit 8 includes positioning portions 16 and 17 as shown in FIG. 4. The positioning portions 16 and 17 are provided in the vicinity of both ends of the keyboard unit 8 so as to protrude in a longitudinal direction thereof (Y direction shown in FIG. 4). Formed in the positioning portion 16 are, for example, a plurality of positioning holes 18 spaced away from each other in an X direction perpendicular to the longitudinal direction (Y direction). Positioning jigs are inserted into the positioning holes 18 at a time of alignment (positioning) described below, for example. Formed in the positioning portion 17 is, for example, a concave hole 19. A positioning jig is aligned to the concave hole 19 at the time of alignment described below.

The frame 10 is made of resin and, as shown in FIG. 4, is divided into a plurality of frames 10a, 10b, and 10c. The frame 10 is divided so as to correspond to a plurality of areas that partition an area of the keyboard unit 8 on which the plurality of keys 8a are arranged. It should be noted that the frame 10 is divided into three in the example. However, the number of the division is not limited thereto, and the frame 10 may be divided into four or more. Accordingly, keyboards having a variety of key arrangements can be supported.

The frames 10a, 10b, and 10c are each provided with a plurality of openings 21. Inserted into the plurality of openings 21 are the keys 8a of the keyboard unit 8.

Provided to surfaces on the keyboard unit 8 side of the frames 10a, 10b, and 10c are, as shown in FIG. 4, a plurality of welding pins 22 so as to protrude at positions corresponding to the plurality of welding holes 15. As shown in FIG. 4, the welding pins 22 of the frame 10 are inserted into the welding holes 15 of the keyboard unit 8, and welded at a plurality of welding points 23 as shown in FIG. 5, thereby fixed to each other.

Formed on the frame 10a is a positioning portion 24 at a position to be aligned with respect to the positioning portion 16 at the time of alignment as shown in FIG. 4. The positioning portion 24 is formed with an elongate hole 25 whose longitudinal direction is the X direction. The elongate hole 25 functions as an escape space for a cushion 9 as shown in FIG. 6. The positioning portion 24 is provided as being sandwiched between the first casing 7a and the keyboard unit 8 as shown in FIG. 6. A height in a thickness direction (Z direction of FIG. 6) of the positioning portion 24 is set to a predetermined height so as to determine a thickness of the first casing 7a and a thickness of the keyboard unit 8. It should be noted that the frame 10c may not be provided with the positioning portion 24.

The first casing 7a is made of metal such as aluminum. Formed on the first casing 7a are, as shown in FIG. 4, a plurality of openings 7c into which the plurality of keys 8a are inserted respectively. Formed on the first casing 7a are positioning holes 26 in the vicinity of both ends of the first casing 7a in a longitudinal direction thereof (Y direction) at positions corresponding to the positioning portions 16 and 17. The positioning holes 26 are provided such that a longitudinal direction thereof becomes the X direction, for example. The cushions 9 are respectively inserted into the positioning holes 26 to be arranged in predetermined areas on a surface of the first casing 7a as shown in FIGS. 5 and 6. The inserted cushions 9 are inserted, as shown in FIGS. 5 and 6, into the positioning holes 26 of the first casing 7a and the concave hole 19 of the positioning portion 17. For example, the cushions 9 have a longitudinal direction in the X direction perpendicular to the longitudinal direction (Y direction) of the main body portion 3. The cushions 9 absorb a shock caused when the display portion 2 is folded with respect to the main body portion 3.

The first casing 7a and the frame 10 are detachably bonded using, for example, double-sided tapes 20. The double-sided tapes 20 are attached between the first casing 7a and the frame 10, for example, linearly along the keys 8a that are adjacent to each other in the longitudinal direction (Y direction of FIG. 4) of the first casing 7a. The double-sided tape 20 are divided by, for example, a plurality of perforations 27 that are formed at predetermined intervals in the longitudinal direction of the first casing 7a. The perforations 27 are formed to align with each other at a plurality of positions in at least one axial direction (Y direction of FIG. 4). It should be noted that division intervals of the double-sided tapes 20, in other words, intervals of the perforations 27, may be equal or not.

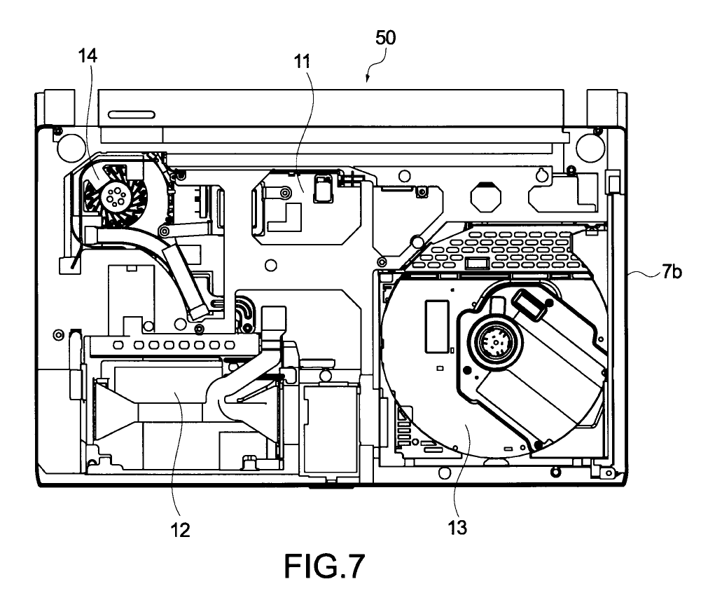

FIG. 7 is a plan view of the electronic component built-in unit 50 of the electronic device 1.

The electronic component built-in unit 50 includes the second casing 7b. Accommodated in the second casing 7b are a system board 11, a hard disk drive 12, an optical disc drive 13, and a cooling unit 14 having a cooling fan.

Electronic components (not shown) such as a CPU (Central Processing Unit), a main memory, a graphic processing circuit, and various interface control circuits are implemented on a back surface of the system board 11. The hard disk drive 12 is connected to a connector portion of the system board 11 via a flexible cable. The cooling unit 14 cools high-heat-generating elements such as the CPU and the graphic processing circuit.

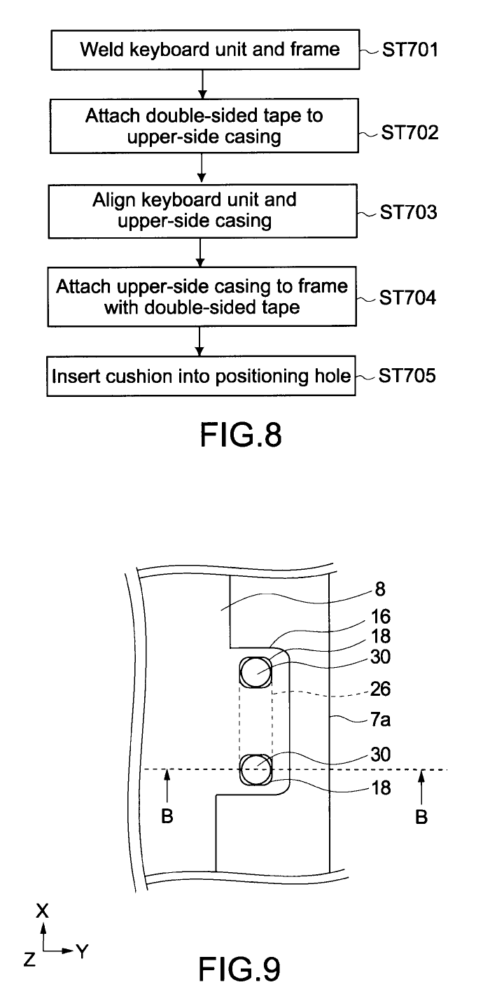

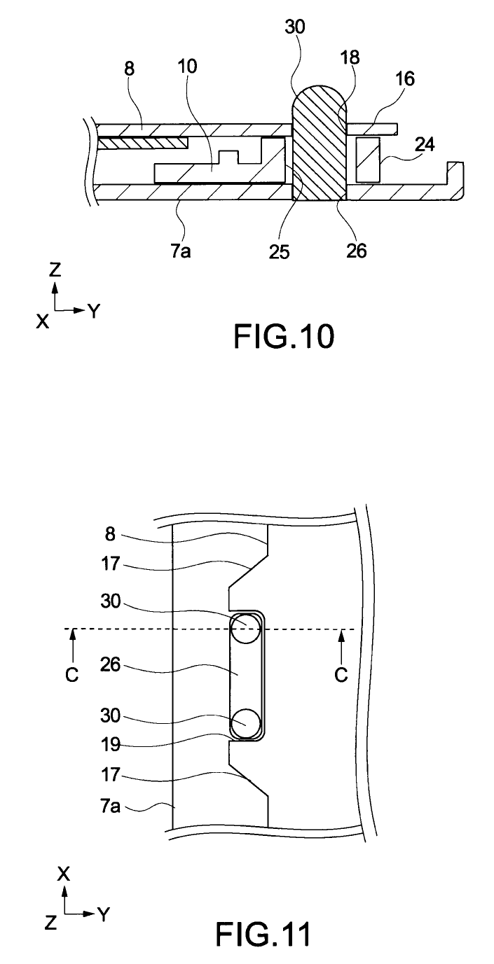

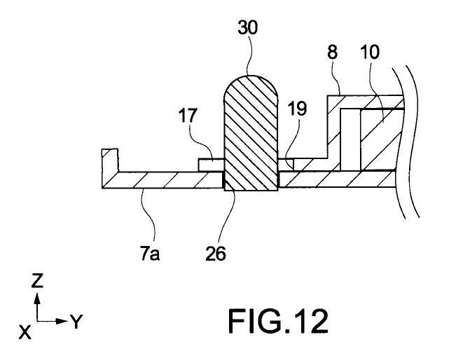

FIG. 8 is a flowchart showing a bonding step of the keyboard unit 8 to the first casing 7a. FIG. 9 is a plan view showing the vicinity of the positioning portion 16 at the time of alignment. FIG. 10 is a cross-sectional view taken along the line B-B in the vicinity of the positioning portion 16 shown in FIG. 9. FIG. 11 is a plan view showing the vicinity of the positioning portion 17 at the time of alignment. FIG. 12 is a cross-sectional view taken along the line C-C of the positioning portion 17 shown in FIG. 11.

As show in the figures, for example, the welding pins 22 of the frame 10 are fitted into the welding holes 15 on the upper surface 8b of the keyboard unit 8, and welded at the plurality of welding points 23 (ST701). Through this step, the keyboard unit 8 and the frame 10 are fixed to each other. At this time, since the frames 10a, 10b, and 10c of different shapes are prepared in advance in conformity with the positions of the keys 8a of the keyboard unit 8, the keyboard unit 8 and the frame 10 can be welded to each other easily even when the frames are welded to a keyboard having keys at different positions.

Next, the double-sided tapes 20 are attached to a back surface 7d (see FIG. 6) side of the first casing 7a (ST702). At this time, the double-sided tapes 20 are attached linearly in the longitudinal direction (Y direction of FIG. 4) of the first casing 7a along the respective keys 8a that are adjacent to each other in the longitudinal direction (Y direction) of the first casing 7a. That is, the double-sided tapes 20 are attached to positions located between the openings 7C adjacent to each other in the X direction of FIG. 4 on the back surface 7d of the first casing 7a. The double-sided tapes 20 are not attached to positions located between the openings 7C adjacent to each other in the Y direction of FIG. 4 on the back surface 7d of the first casing 7a.

As shown in FIGS. 9 and 10, jigs 30 are used to align the positioning hole 26 of the first casing 7a and the positioning portion 16 of the keyboard unit 8 with each other. Together with this alignment, the jigs 30 are used to align the positioning hole 26 of the first casing 7a and the positioning portion 17 of the keyboard unit 8 as shown in FIGS. 11 and 12 (ST703).

The alignment of the first casing 7a and the keyboard unit 8 will be described in detail.

First, the jigs 30 are each inserted into the positioning hole 26 of the first casing 7a as shown in FIG. 9 and 10, and the jigs 30 are each inserted into the positioning hole 26 of the first casing 7a (ST 703). Accordingly, the first casing 7a is disposed to a predetermined position with respect to the jigs 30. At this time, as shown in FIG. 9, the two jigs 30 are inserted into the positioning hole 26 in the vicinity of both ends of the positioning hole 26 in the longitudinal direction thereof (X direction of FIG. 9), for example. Accordingly, the position of the positioning hole 26 of the first casing 7a with respect to the two jigs 30 is determined. Furthermore, as shown in FIG. 11, the two jigs 30 are inserted into the positioning hole 26 in the vicinity of both ends of the positioning hole 26 in the longitudinal direction thereof (X direction of FIG. 11), for example. Accordingly, the position of the positioning hole 26 of the first casing 7a with respect to the two jigs 30 is determined.

Subsequently, the jigs 30 are each inserted into the two positioning holes 18 of the keyboard unit 8 as shown in FIGS. 9 and 10, and the two jigs 30 are fitted into the concave hole 19 of the keyboard unit 8 as shown in FIGS. 11 and 12. At this time, as shown in FIG. 9, the jigs 30 are inserted into the two positioning holes 18 of the positioning portion 16, respectively. Accordingly, the positioning portion 16 of the keyboard unit 8 is positioned with respect to the first casing 7a. Furthermore, as shown in FIG. 11, the jigs 30 are fitted in the vicinity of the both ends of the concave hole 19 of the positioning portion 17 in the longitudinal direction. Accordingly, the positioning portion 17 of the keyboard unit 8 is positioned with respect to the first casing 7a. As described above, the keyboard unit 8 is positioned with respect to the first casing 7a.

Next, the keyboard unit 8 is pressed to the first casing 7a, for example, and thus the frame 10 that is welded to the keyboard unit 8 and the first casing 7a are detachably bonded to each other with the double-sided tapes 20 (ST704).

Then, the first casing 7a bonded to the frame 10 by the double-sided tapes 20 is detached from the jigs 30 together with the keyboard unit 8. The cushions 9 are attached to the positioning holes 26 into which the jigs 30 have been inserted. Accordingly, as shown in FIG. 6, part of a cushion 9 is inserted into the positioning hole 26 and the elongate hole 25, and a cushion 9 is similarly inserted into the positioning hole 26 and the concave hole 19.

According to this embodiment as described above, the frame 10 made of resin is welded to the upper surface 8b of the keyboard unit 8, and the first casing 7a is detachably bonded to the frame 10 with the double-sided tapes 20. Accordingly, there is obtained a structure in which a gap is not generated between the upper surface 8b of the keyboard unit 8 and the first casing 7a, with the result that rigidity of the keyboard can be enhanced. That is, there is obtained a structure in which the keyboard unit 8 is not attached on a electronic component built-in unit 50 side but attached on a first casing 7a side through the frame 10, and thus rigidity of the keyboard unit 8 (main body portion 3) can be enhanced. Furthermore, since the first casing 7a is made of metal and is bonded to the frame 10 with the double-sided tapes 20, it is possible to detach the first casing 7a from the frame 10 without damages when maintenance etc. is necessary, and to reuse the first casing 7a.

As described above, since the frame 10 made of resin is interposed between the keyboard unit 8 and the first casing 7a, the first casing 7a can be replaced when the first casing 7a is broken, for example. Furthermore, when the keyboard unit 8 is broken, the keyboard unit 8 to which the frame 10 made of resin is welded is replaced, whereby the number of replacement parts can be suppressed to the minimum.

Furthermore, the frame 10 is welded to the keyboard unit 8 in advance (ST701), and after that, the keyboard unit 8 is aligned with the first casing 7a using the jigs 30. In this case, the alignment of the frame 10 and the first casing 7a is unnecessary and accordingly productivity can be enhanced.

Since the double-sided tapes 20 are attached linearly in the longitudinal direction (Y direction of FIG. 4) of the first casing 7a, the double-sided tapes 20 can be attached to the back surface 7d of the first casing 7a easily without being affected by the arrangement of the keys 8a. Moreover, the double-sided tapes 20 are divided by the perforations 27 in the longitudinal direction of the first casing 7a (Y direction of FIG. 4), and attached to the first casing 7a and the frame 10 therebetween. For that reason, it is possible to peel off the first casing 7a from the frame 10 more easily when the first casing 7a is detached from the frame 10. In other words, rework performance of the first casing 7a can be enhanced, and a task of reusing the first casing 7a and the keyboard unit 8 can be facilitated.

The frame 10 is divided into the plurality of frames 10a, 10b, and 10c. Accordingly, in a case where the first casing 7a made of metal and the frame 10 made of resin are detachably bonded to each other with the double-sided tapes 20, even when temperatures of the first casing 7a and the frame 10 change from high to low, it is possible to absorb a difference in contraction ratio due to a temperature difference between the respective materials, and the first casing 7a and the frame 10 can be bonded more reliably to each other.

Furthermore, in the keyboard unit 8, the arrangement of the keys varies depending on destination positions. It should be noted that the entire arrangement of the keys is not varied but is partially varied. Therefore, a different frame is used only for a different part and a common frame is partially used, and thus a keyboard that is different in each destination position can be structured. Accordingly, the number of molds for the frames 10a, 10b, and 10c and the like can be reduced. That is, compared with a case where a mold for a frame corresponding to an actual size of a keyboard unit is manufactured for each destination position, a single mold for a common frame is manufactured and only molds for different frames are manufactured for each destination position, with the result that costs for molds can be reduced.

Moreover, since a different frame is partially used for each destination position, a position of a bar of the first casing 7a in a lateral direction thereof (X direction of FIG. 4) is varied for each destination position. In contrast to this, a position of a bar 7d (bar 10d or the like of the frame 10) of the first casing 7a in the longitudinal direction thereof (Y direction of FIG. 4) is not varied for each destination position. In other words, by attaching the double-sided tapes 20 to the bar 7d of the first casing 7a in the longitudinal direction thereof (Y direction of FIG. 4), the double-sided tapes 20 can be attached to the keyboard unit 8 in a common step for any destination position, with the result that the number of steps cab be reduced.

The cushions 9 are inserted into the positioning holes 26 of the first casing 7a that is bonded to the frame 10. That is, holes for providing the cushions 9 to the first casing 7a (positioning holes 26) can be used for the positioning of the keyboard unit 8 and the first casing 7a. The first casing 7a is made of metal and is an appearance part, and accordingly positioning holes cannot be formed on the first casing 7a. However, in this embodiment, the holes for providing the cushions 9 (positioning holes 26) are used for the alignment, and then the cushions 9 are inserted into the positioning holes 26, whereby the appearance of the first casing 7a is prevented from being impaired.

The positioning holes 26 are formed on the first casing 7a, and the keyboard unit 8 includes the positioning portions 16 and 17. The positioning portion 16 has the two positioning holes 18 formed thereon at the positions corresponding to the both ends of the positioning hole 26 in the longitudinal direction thereof (X direction of FIG. 9) and, at the time of positioning, the jigs 30 are inserted into the positioning holes 18. Accordingly, the position of the keyboard unit 8 with respect to the first casing 7a can be correctly determined in the X and Y directions of FIG. 9. On the other hand, the positioning portion 17 is formed with the concave hole 19 whose longitudinal direction is the X direction as shown in FIG. 11. At the time of the alignment, the two jigs 30 are fitted into the both ends of the concave hole 19 in the longitudinal direction thereof. Accordingly, the keyboard unit 8 is positioned with respect to the first casing 7a in the X direction. The concave hole 19 has a concave shape, and thus the positioning in the Y direction can be made more easily.

The frame 10 made of resin has a thickness (height) thinner than a thickness of the keys 8a as shown in FIG. 6. Thus, a thickness obtained when the keyboard unit 8 and the first casing 7a are integrated while sandwiching the frame 10 can be prevented from becoming thick, and a reduction in weight can be realized.

The first casing 7a is the appearance part over an entire surface (front surface) of the main body portion 3. Thus, flexibility of design is increased, and the electronic device 1 that is more excellent in design can be realized.

The present invention is not limited to the embodiment described above, and as a matter of course, various updates can be added thereto without departing from the gist of the present invention.

In the embodiment of the present invention, the example in which after the frame 10 is welded to the keyboard unit 8 (ST701), the double-sided tapes 20 are attached to the first casing 7a (ST702) has been described. However, the present invention is not limited thereto, and for example, the order of ST701 and ST702 may be reversed. In other words, after the double-sided tapes 20 are attached to the first casing 7a, the frame 10 may be welded to the keyboard unit 8. In this case as well, the first casing 7a and the keyboard unit 8 can be detachably bonded to each other.

In the embodiment described above, the example in which the double-sided tapes 20 are attached to the back surface 7d (see FIG. 6) of the first casing 7a (ST702) has been described. However, the member to which the double-sided tapes 20 are attached is not limited thereto. For example, instead of being attached to the back surface 7d (see FIG. 6), the double-sided tapes 20 may be attached to the frame 10 that is welded to the keyboard unit 8. In this case as well, the first casing 7a and the keyboard unit 8 can be detachably bonded to each other similarly to the embodiment described above.

In the embodiment described above, the example in which the perforations 27 are formed in the double-sided tapes 20 and then double-sided tapes 20 are divided in the longitudinal direction has been described. However, a double-sided tape without perforations 27 may be used instead of the double-sided tape 20. Thus, reduction in costs or enhancement of a bonding force may be achieved, for example.

In the embodiment described above, the example in which the double-sided tapes 20 are not attached to the positions located between the openings 7C adjacent to each other in the Y direction of FIG. 4 on the back surface 7d of the first casing 7a has been described. However, the double-sided tapes 20 may be attached to the positions located between the openings 7C adjacent to each other in the Y direction of FIG. 4 on the back surface 7d of the first casing 7a. Thus, the bonding force may be enhanced.

In the embodiment described above, the example in which the keyboard unit 8 includes the positioning portions 16 and 17 and the first casing 7a includes the positioning holes 26 formed thereon has been described. However, the present invention is not limited thereto. For example, the keyboard unit 8 may include a plurality of positioning portions each having one positioning hole to which the jig 30 is inserted, instead of the positioning portion 16, and the first casing 7a may include openings at positions corresponding to those positioning holes. In this case as well, similarly to the embodiment described above, the first casing and the keyboard unit can be aligned with each other.

The present application contains subject matter related to that disclosed in Japanese Priority Patent Application JP 2008-180911 filed in the Japan Patent Office on Jul. 11, 2008, the entire contents of which is hereby incorporated by reference.

What is claimed is:

1. A keyboard, comprising:
a keyboard unit including
a surface made of metal, and
a plurality of keys disposed on the surface;
a frame made of resin to be joined to the surface, the frame including a plurality of first openings into which the respective keys are inserted; and
an exterior panel made of metal to be detachably bonded to the frame, the exterior panel including a plurality of second openings into which the respective keys protruding from the respective first openings of the frame are inserted.

2. The keyboard according to claim 1,
wherein the exterior panel and the frame are bonded to each other with a tape to which an adhesive is applied on both sides.

3. The keyboard according to claim 2,
wherein the tape is a tape having perforations for facilitating separation.

4. The keyboard according to claim 3,
wherein the frame is divided into areas corresponding to a plurality of areas that partition an area of the keyboard unit on which the plurality of keys are arranged.

5. The keyboard according to claim 4,
wherein the exterior panel includes a hole used for positioning with respect to the keyboard unit, into which a shock-absorbing member is inserted.

6. The keyboard according to claim 5,
wherein the keyboard is connected to a display portion including a display screen so that the display portion is foldable with respect to the keyboard, and
wherein the shock-absorbing member absorbs a shock caused between the keyboard and the display portion when the display portion is folded with respect to the keyboard.

7. An electronic device, comprising:
a keyboard including
a keyboard unit including a surface made of metal and a plurality of keys disposed on the surface,
a frame made of resin to be joined to the surface, the frame including a plurality of first openings into which the respective keys are inserted, and
an exterior panel made of metal to be detachably bonded to the frame, the exterior panel including a plurality of second openings into which the respective keys protruding from the respective first openings of the frame are inserted; and
a display portion displaying an image based on a display signal that is generated in the keyboard by pressing of the keys of the keyboard.

8. A keyboard manufacturing method, comprising:
joining a frame made of resin to a surface made of metal of a keyboard unit, the frame including a plurality of first openings, the keyboard unit including the surface and a plurality of keys disposed on the surface, in a state where the respective keys are inserted into the first openings;
aligning, with the frame, an exterior panel including a plurality of second openings into which the respective keys are inserted; and
detachably bonding the exterior panel to the frame in a state where the respective keys are inserted into the second openings.

9. The keyboard manufacturing method according to claim 8,
wherein the keyboard unit is provided with a first positioning hole used for alignment with the exterior panel, and the exterior panel is provided with a second positioning hole used for alignment with the keyboard unit,
wherein the keyboard unit and the exterior panel are aligned with each other by inserting a jig into the first positioning hole and the second positioning hole, and
wherein the bonding is performed using a tape to which an adhesive is applied on both sides.

10. The keyboard manufacturing method according to claim 9,
wherein the keyboard constitutes a main body portion of a folding-type laptop personal computer, and
wherein the second positioning hole of the exterior panel that is bonded to the frame is inserted with a shock-absorbing member, the shock-absorbing member absorbing a shock caused when a display portion that is provided so as to be openable with respect to the main body portion is closed with respect to the main body portion.
